(19) United States
(12) Patent Application Publication
(10) Pub. No.: US 2025/0048615 A1
(43) Pub. Date: Feb. 6, 2025

(54) 3D STACKED SEMICONDUCTOR DEVICE, MANUFACTURING METHOD THEREFOR, AND ELECTRONIC EQUIPMENT

(71) Applicant: BEIJING SUPERSTRING ACADEMY OF MEMORY TECHNOLOGY, Beijing (CN)

(72) Inventors: Xuezheng Ai, Beijing (CN); Xiangsheng Wang, Beijing (CN); Guilei Wang, Beijing (CN); Jin Dai, Beijing (CN); Chao Zhao, Beijing (CN); Wenhua Gui, Beijing (CN)

(73) Assignee: BEIJING SUPERSTRING ACADEMY OF MEMORY TECHNOLOGY, Beijing (CN)

(21) Appl. No.: 18/692,912

(22) PCT Filed: Jun. 8, 2023
(86) PCT No.: PCT/CN2023/099226

§ 371 Date: Mar. 18, 2024

(30) Foreign Application Priority Data
Jan. 30, 2023 (CN) 202310118760.1

(51) Int. Cl. H10B 12/00

(52) U.S. Cl. CPC H10B 12/30; H10B 12/05

(57) ABSTRACT

A 3D stacked semiconductor device, a manufacturing method therefor, and an electronic equipment are disclosed. The 3D stacked semiconductor device includes a plurality of transistors distributed in different layers and stacked along a direction perpendicular to a base substrate; a word line penetrating through the transistors of the different layers; and a plurality of protective layers corresponding to the plurality of transistors respectively; wherein each transistor includes a semiconductor layer surrounding a side wall of the word line, a gate insulation layer disposed between the side wall of the word line and the semiconductor layer, a plurality of semiconductor layers of the plurality of transistors are disposed at intervals in a direction in which the word line extends; each of the protective layers respectively surrounds and covers an outer side wall of a corresponding semiconductor layer, and two adjacent protective layers are disconnected from each other.

### CROSS-REFERENCE TO RELATED APPLICATIONS

The present application is a U.S. National Phase Entry of International Application PCT/CN2023/099226 having an international filing date of Jun. 8, 2023, which claims priority to Chinese Patent Application No. 202310118760.1, filed with the CNIPA on Jan. 30, 2023 and entitled “3D Stacked Semiconductor Device, Manufacturing Method Therefor, and Electronic Equipment”, contents of which should be construed as being incorporated herein by reference.

### TECHNICAL FIELD

Embodiments of the present disclosure relate to, but are not limited to, the field of semiconductor technologies, in particular to a three-dimensional (3D) stacked semiconductor device, a method for manufacturing the 3D stacked semiconductor device, and an electronic equipment.

### BACKGROUND

With update of technology iteration, a Dynamic Random Access Memory (DRAM) needs to obtain a higher storage density. A three-dimensional (3D) DRAM is an important development direction. For the 3D DRAM, a parasitic transistor produced by a device design and a process affects normal writing and reading of data adversely when the DRAM works.

### SUMMARY

The following is a summary of subject matter described herein in detail. The summary is not intended to limit the scope of protection of claims.

An embodiment of the present disclosure provides a 3D stacked semiconductor device, including: a plurality of transistors distributed in different layers and stacked along a direction perpendicular to a base substrate; a word line penetrating through the transistors of the different layers; and a plurality of protective layers respectively corresponding to the plurality of transistors; wherein each transistor includes a semiconductor layer surrounding a side wall of the word line, and a gate insulation layer disposed between the side wall of the word line and the semiconductor layer; a plurality of semiconductor layers of the plurality of transistors are disposed at intervals in a direction in which the word line extends; each of the protective layers respectively surrounds and covers an outer side wall of a semiconductor layer of a corresponding transistor, and two adjacent protective layers are disconnected from each other.

In some embodiments, the plurality of transistors which are stacked further include: insulation layers and conductive layers alternately distributed in turn from bottom to top along the direction perpendicular to the base substrate; and a through hole penetrating through each insulation layer and each conductive layer, wherein the word line, the gate insulation layers surrounding the side wall of the word line, the plurality of semiconductor layers surrounding the gate insulation layers, the protective layers surrounding the semiconductor layers are sequentially distributed within the through hole from inside to outside, and the protective layers are in contact with the semiconductor layers; wherein each gate insulation layer is exposed between two adjacent semiconductor layers, each insulation layer is filled between two adjacent semiconductor layers, and the insulation layer is in contact with the exposed gate insulation layer; each conductive layer includes a first electrode and a second electrode which are independent of each other, one of the first electrode and the second electrode is a source of a transistor, and the other of the first electrode and the second electrode is a drain of the transistor.

In some embodiments, an aperture of the through hole corresponding to a first region of each conductive layer is equal to an aperture of the through hole corresponding to a second region of each insulation layer; only a side wall of the conductive layer is exposed within the through hole, and only a side wall of the insulation layer is exposed within the through hole; and the semiconductor layer is distributed on the side wall of the conductive layer.

In some embodiments, the plurality of protective layers extend along the direction perpendicular to the base substrate and are disconnected at upper and lower surfaces of the insulation layers.

In some embodiments, each protective layer is in contact with a semiconductor layer of a corresponding transistor, and the protective layer covers a region in a side wall of the semiconductor layer that is not in contact with the conductive layer.

In some embodiments, the protective layers are further distributed on side walls of the conductive layers and in contact with the side wall of the conductive layer.

In some embodiments, a material of the protective layers is different from that of the insulation layers.

In some embodiments, the plurality of stacked transistors further include a fifth insulation layer covering outer side walls of the protective layers.

An embodiment of the present disclosure provides an electronic equipment including the 3D stacked semiconductor device as described in any of the above embodiments.

An embodiment of the present disclosure provides a method for manufacturing a 3D stacked semiconductor device, wherein the 3D stacked semiconductor device includes: a plurality of transistors distributed in different layers and stacked along a direction perpendicular to a base substrate; a word line penetrating through the transistors of the different layers; and a plurality of protective layers respectively corresponding to the plurality of transistors; the method for manufacturing the 3D stacked semiconductor device includes: providing a base substrate, alternately depositing first insulation thin films and conductive thin films in turn on the base substrate, and patterning to form a stacked structure, wherein the stacked structure includes a stack of first insulation layers and conductive layers that are alternately disposed, each conductive layer includes a preset electrode pattern, and the preset electrode pattern contains a first electrode and a second electrode of a transistor to be formed; forming a through hole penetrating through the stacked structure in the direction perpendicular to the base substrate, wherein a side wall of the through hole exposes each conductive layer, and filling an insulation thin film within the through hole to form a sacrificial layer of the word line; and etching each conductive layer to enable the first electrode and the second electrode in the preset electrode pattern to be disconnected from each other, wherein the first electrode is in contact with the sacrificial layer, and the second electrode is in contact with the sacrificial layer; forming a plurality of protective layers respectively corresponding to the plurality of transistors, wherein the plurality of protective layers respectively cover side walls of the sacrificial layer and the conductive layers, and two adjacent protective layers are disconnected from each other; removing the sacrificial layer, sequentially depositing a semiconductor thin film and a gate insulation thin film on the side wall of the through hole, and depositing a gate electrode thin film filling the through hole to form a plurality of semiconductor layers and gate insulation layers of the transistors, and the word line, wherein the semiconductor layers are in contact with the first electrodes, the second electrodes, and the protective layers; gate electrodes of the transistors of different layers are part of the word line; and etching and removing the semiconductor layers within regions corresponding to the first insulation layers within the through hole.

In some embodiments, before etching the conductive layers, the method further includes: etching from top to bottom of the stacked structure along the direction perpendicular to the base substrate to expose side walls of the conductive layers and side walls of the first insulation layers; forming the plurality of protective layers corresponding to the plurality of transistors respectively includes: depositing a protective layer thin film on the side walls of the conductive layers, the side wall of the sacrificial layer, and the side walls of the first insulation layers, etching the protective layer thin film from top to bottom along the direction perpendicular to the base substrate to remove the protective layer thin film on the side walls of the first insulation layers, and forming the protective layers covering the side walls of the conductive layers and the side wall of the sacrificial layer.

In some embodiments, after forming the protective layers and before removing the sacrificial layer, the method further includes: depositing a third insulation thin film, and forming a third insulation layer disposed on side walls of the protective layers and side walls of the first insulation layers; before etching and removing the semiconductor layers within the regions corresponding to the first insulation layers within the through hole, the method further includes: etching the third insulation layer and the first insulation layers to expose the side walls of the protective layer and the side walls of the semiconductor layers within the regions corresponding to the first insulation layers within the through hole.

Other features and advantages of the present disclosure will be set forth in the following specification, and moreover, partially become apparent from the specification, or are understood by implementing the present disclosure. The objectives and advantages of the present disclosure may be achieved through structures particularly pointed out in the specification and the drawings.

Other aspects may be understood upon reading and understanding the drawings and detailed description.

### BRIEF DESCRIPTION OF DRAWINGS

Accompanying drawings are used to provide further understanding of technical solutions of the present disclosure, constitute a part of the specification, and are used to explain the technical solutions together with the embodiments of the present disclosure but not to form limitations on the technical solutions of the present disclosure.

FIG. 1A is a schematic cross-sectional view of a 3D stacked semiconductor device according to an exemplary embodiment along a C1 direction parallel to a base substrate.

FIG. 1B is a schematic cross-sectional view of the 3D stacked semiconductor device shown in FIG. 1A along a C2 direction perpendicular to the base substrate.

FIG. 1C is a schematic cross-sectional view of the 3D stacked semiconductor device shown in FIG. 1A along a C3 direction perpendicular to the base substrate.

FIG. 2A is a three-dimensional schematic view of a 3D stacked semiconductor device according to an exemplary embodiment after a stacked structure of a conductive thin film and an insulation thin film are formed.

FIG. 2B is a schematic cross-sectional view of the 3D stacked semiconductor device shown in FIG. 2A along the C1 direction.

FIG. 2C is a schematic cross-sectional view of the 3D stacked semiconductor device shown in FIG. 2A along the C2 direction.

FIG. 2D is a schematic cross-sectional view of the 3D stacked semiconductor device shown in FIG. 2A along the C3 direction.

FIG. 3A is a three-dimensional schematic view of a 3D stacked semiconductor device according to an exemplary embodiment after a conductive layer is formed.

FIG. 3B is a schematic cross-sectional view of the 3D stacked semiconductor device shown in FIG. 3A along the C1 direction.

FIG. 3C is a schematic cross-sectional view of the 3D stacked semiconductor device shown in FIG. 3A along a C2′ direction.

FIG. 3D is a schematic cross-sectional view of the 3D stacked semiconductor device shown in FIG. 3A along the C3 direction.

FIG. 4A is a three-dimensional schematic view of a 3D stacked semiconductor device according to an exemplary embodiment after a capacitor is formed.

FIG. 4B is a schematic cross-sectional view of the 3D stacked semiconductor device shown in FIG. 4A along the C1 direction.

FIG. 4C is a schematic cross-sectional view of the 3D stacked semiconductor device shown in FIG. 4A along the C2′ direction.

FIG. 4D is a schematic cross-sectional view of the 3D stacked semiconductor device shown in FIG. 4A along the C3 direction.

FIG. 5A is a three-dimensional schematic view of a 3D stacked semiconductor device according to an exemplary embodiment after a sacrificial layer is formed.

FIG. 5B is a schematic cross-sectional view of the 3D stacked semiconductor device shown in FIG. 5A along the C1 direction.

FIG. 5C is a schematic cross-sectional view of the 3D stacked semiconductor device shown in FIG. 5A along the C2 direction.

FIG. 5D is a schematic cross-sectional view of the 3D stacked semiconductor device shown in FIG. 5A along the C3 direction.

FIG. 6A is a schematic three-dimensional view of a 3D stacked semiconductor device according to an exemplary embodiment after an insulation thin film between preset electrode patterns is etched.

FIG. 6B is a schematic cross-sectional view of the 3D stacked semiconductor device shown in FIG. 6A along the C1 direction.

FIG. 6C is a schematic cross-sectional view of the 3D stacked semiconductor device shown in FIG. 6A along the C2 direction.

FIG. 6D is a schematic cross-sectional view of the 3D stacked semiconductor device shown in FIG. 6A along the C3 direction.

FIG. 7A is a three-dimensional schematic view of a 3D stacked semiconductor device according to an exemplary embodiment after a first electrode and a second electrode are formed.

FIG. 7B is a schematic cross-sectional view of the 3D stacked semiconductor device shown in FIG. 7A along the C1 direction.

FIG. 7C is a schematic cross-sectional view of the 3D stacked semiconductor device shown in FIG. 7A along the C2 direction.

FIG. 7D is a schematic cross-sectional view of the 3D stacked semiconductor device shown in FIG. 7A along the C3 direction.

FIG. 8A is a three-dimensional schematic view of a 3D stacked semiconductor device according to an exemplary embodiment after a protective layer is formed.

FIG. 8B is a schematic cross-sectional view of the 3D stacked semiconductor device shown in FIG. 8A along the C1 direction.

FIG. 8C is a schematic cross-sectional view of the 3D stacked semiconductor device shown in FIG. 8A along the C2 direction.

FIG. 8D is a schematic cross-sectional view of the 3D stacked semiconductor device shown in FIG. 8A along the C3 direction.

FIG. 9A is a three-dimensional schematic view of a 3D stacked semiconductor device according to an exemplary embodiment after a sacrificial layer is removed.

FIG. 9B is a schematic cross-sectional view of the 3D stacked semiconductor device shown in FIG. 9A along the C1 direction.

FIG. 9C is a schematic cross-sectional view of the 3D stacked semiconductor device shown in FIG. 9A along the C2 direction.

FIG. 9D is a schematic cross-sectional view of the 3D stacked semiconductor device shown in FIG. 9A along the C3 direction.

FIG. 10A is a three-dimensional schematic view of a 3D stacked semiconductor device according to an exemplary embodiment after a semiconductor layer and a gate electrode are formed.

FIG. 10B is a schematic cross-sectional view of the 3D stacked semiconductor device shown in FIG. 10A along the C1 direction.

FIG. 10C is a schematic cross-sectional view of the 3D stacked semiconductor device shown in FIG. 10A along the C2 direction.

FIG. 10D is a schematic cross-sectional view of the 3D stacked semiconductor device shown in FIG. 10A along the C3 direction.

FIG. 11A is a three-dimensional schematic view of a 3D stacked semiconductor device according to an exemplary embodiment after a semiconductor layer between layers is exposed.

FIG. 11B is a schematic cross-sectional view of the 3D stacked semiconductor device shown in FIG. 11A along the C1 direction.

FIG. 11C is a schematic cross-sectional view of the 3D stacked semiconductor device shown in FIG. 11A along the C2 direction.

FIG. 11D is a schematic cross-sectional view of the 3D stacked semiconductor device shown in FIG. 11A along the C3 direction.

FIG. 12A is a three-dimensional schematic view of a 3D stacked semiconductor device according to an exemplary embodiment after a semiconductor layer between layers is etched.

FIG. 12B is a schematic cross-sectional view of the 3D stacked semiconductor device shown in FIG. 12A along the C1 direction.

FIG. 12C is a schematic cross-sectional view of the 3D stacked semiconductor device shown in FIG. 12A along the C2 direction.

FIG. 12D is a schematic cross-sectional view of the 3D stacked semiconductor device shown in FIG. 12A along the C3 direction.

FIG. 13A is a three-dimensional schematic view of a 3D stacked semiconductor device according to an exemplary embodiment after a fourth insulation layer is formed.

FIG. 13B is a schematic cross-sectional view of the 3D stacked semiconductor device shown in FIG. 13A along the C1 direction.

FIG. 13C is a schematic cross-sectional view of the 3D stacked semiconductor device shown in FIG. 13A along the C2 direction.

FIG. 13D is a schematic cross-sectional view of the 3D stacked semiconductor device shown in FIG. 13A along the C3 direction.

FIG. 14 is a schematic diagram of a preset electrode pattern according to another exemplary embodiment.

FIG. 15 is a flowchart of a method for manufacturing a 3D stacked semiconductor device according to an exemplary embodiment.

### DETAILED DESCRIPTION

The embodiments of the present disclosure will be described in detail below with reference to the accompanying drawings. The embodiments in the present application and features in the embodiments may be combined with each other randomly if there is no conflict.

Unless otherwise defined, technical terms or scientific terms used in the present disclosure shall have general meanings as understood by those of ordinary skills in the art to which the present disclosure pertains.

The embodiments of the present disclosure are not necessarily limited to dimensions shown in the drawings, and shapes and sizes of various components in the drawings do not reflect actual scales. Further, the drawings schematically illustrate ideal examples, but embodiments of the present disclosure are not limited to shapes or values shown in the drawings.

Ordinal numerals such as “first”, “second” and “third” in the present disclosure are provided to avoid confusion between constituent elements, but do not indicate any order, quantity or importance.

In the present disclosure, for convenience, words and expressions indicating orientation or positional relationship such as “middle”, “upper”, “lower”, “front”, “rear”, “vertical”, “horizontal”, “top”, “bottom”, “inner” and “outer” are employed to explain the positional relationship of the constituent elements with reference to the accompanying drawings, they are employed for ease of description and simplification of the description only, but do not indicate or imply that the referred device or element must have a particular orientation, be constructed and operate in a particular orientation, and therefore cannot be construed as limitations on the present disclosure. The positional relationship of the constituent elements is appropriately changed according to a direction in which each constituent element is described. Therefore, it is not limited to the words and expressions described in the present disclosure, and may be appropriately replaced according to situations.

In the present disclosure, the terms “mounted”, “connected” and “connection” are to be understood broadly, unless otherwise expressly specified and defined. For example, a connection may be a fixed connection, a detachable connection, or an integrated connection; it may be a mechanical connection or an electrical connection; it may be direct connection, indirect connection through a middleware, or an internal communication between two elements. For those of ordinary skills in the art, specific meanings of the above terms in the present disclosure may be understood according to actual situations.

In the present disclosure, a transistor refers to an element including at least three terminals, i.e., a gate, a drain, and a source. A transistor has a channel region between a drain (drain terminal, drain region, or drain electrode) and a source (source terminal, source region, or source electrode), and a current can flow through the drain, the channel region, and the source. In the present disclosure, the channel region refers to a region through which a current mainly flows.

In the present disclosure, “parallel” refers to approximately parallel or almost parallel, for example, refers to a state in which the angle formed by two straight lines is above −10 degrees and below 10 degrees, and therefore also includes a state in which the angle is above −5 degrees and below 5 degrees. In addition, “perpendicular” refers to “approximately perpendicular”, for example, refers to a state in which the angle formed by two straight lines is above 80 degrees and below 100 degrees, and therefore also includes a state in which the angle is above 85 degrees and below 95 degrees.

In the present disclosure, “A and B are disposed in a same layer” means that A and B are formed simultaneously through a same one-time patterning process. “An orthographic projection of B is within a range of an orthographic projection of A” means that a boundary of the orthographic projection of B falling within a range of a boundary of the orthographic projection of A, or a boundary of the orthographic projection of A is overlapped with a boundary of the orthographic projection of B.

“A and B are of an integral structure” in the embodiments of the present disclosure may mean that there is no obvious boundary interface, such as an obvious fault or gap, viewed from a microstructure. Generally, connected film layers formed by patterning on one film layer are of an integral structure. For example, A and B are formed in one film layer using a same material and simultaneously formed in a structure with a connection relationship through a same one-time patterning process.

In an embodiment of the present disclosure, a parasitic transistor (referred to as a parasitic MOS) between adjacent transistors between adjacent layers may be eliminated by etching and removing a semiconductor layer between storage unit layers of different layers.

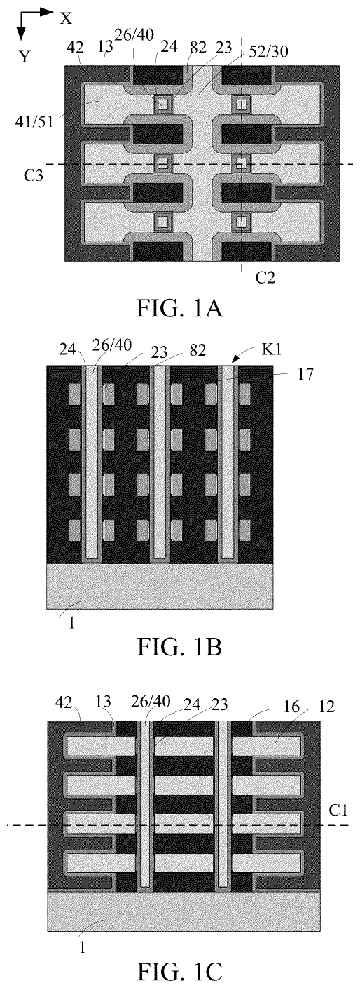

FIG. 1A is a schematic cross-sectional view of a 3D stacked semiconductor device according to an exemplary embodiment along a C1 direction parallel to a base substrate, FIG. 1B is a schematic cross-sectional view of the 3D stacked semiconductor device shown in FIG. 1A along a C2 direction perpendicular to the base substrate, and FIG. 1C is a schematic cross-sectional view of the 3D stacked semiconductor device shown in FIG. 1A along a C3 direction perpendicular to the base substrate. The C2 direction and the C3 direction are perpendicular to each other, as shown in FIGS. 1A, 1B, and 1C, and the 3D stacked semiconductor device according to the embodiment may include: a plurality of transistors distributed in different layers and stacked along a direction perpendicular to a base substrate 1; a word line 40 that penetrates through structures of transistors of different layers, wherein the word line 40 may extend along the direction perpendicular to the base substrate 1; and a plurality of protective layers 82 corresponding to the plurality of transistors respectively; wherein each transistor may include a semiconductor layer 23 surrounding a side wall of the word line 40, and a gate insulation layer 24 disposed between the side wall of the word line 40 and the semiconductor layer 23; a plurality of semiconductor layers 23 of the plurality of transistors are disposed at intervals in a direction in which the word line 40 extends, that is, the plurality of semiconductor layers 23 are distributed in different regions of the side wall of the word line 40; each of the protective layers 82 surrounds and covers an outer side wall of a semiconductor layer 23 of a corresponding transistor, respectively, and two adjacent protective layers 82 are disconnected, that is, a plurality of protective layers 82 corresponding to the plurality of transistors are disposed at intervals. The outer side wall of the semiconductor layer 23 is a side wall of the semiconductor layer 23 away from a gate electrode 26.

In the 3D stacked semiconductor device according to the embodiment, semiconductor layers of transistors of different layers are disposed at intervals, so that a parasitic transistor may be eliminated. In addition, when manufacturing the 3D stacked semiconductor device by disposing a protective layer, the semiconductor layers of the transistors may be avoided from being exposed, so that the semiconductor layers may be avoided from being damaged, and reliability and stability of a channel material of the device may be improved.

In some embodiments, each transistor may further include a gate electrode 26, the gate electrode 26 may extend along the direction perpendicular to the base substrate 1, and the gate electrode 26 of each of the transistors is part of the word line 40.

In some embodiments, each transistor may further include a first electrode 51 and a second electrode 52, and a channel between the first electrode 51 and the second electrode 52 may be a horizontal channel. The horizontal channel means that a carrier transport direction in the channel is in a plane parallel to the base substrate, but it is not limited to that the carrier transport direction must be one direction. In practical applications, the carrier transport direction generally extends along one direction, but locally, it is related to a shape of a semiconductor layer. In other words, the horizontal channel does not represent that it must extend along one direction in a horizontal plane, but may extend along different directions. For example, when the semiconductor layer is in an annular shape, a source contact region and a drain contact region on the annular semiconductor layer are parts of the annular shape. At this time, carriers generally extend along one direction from the source contact region to the drain contact region, but may not be along one direction locally. Of course, the carrier transport direction is in the plane parallel to the base substrate, which is also a macroscopic concept, which is not limited to being absolutely parallel to the base substrate. The channel between the first electrode and the second electrode as claimed by the present application is a channel not perpendicular to the base substrate.

In some embodiments, the gate electrode 26 may extend only along the direction perpendicular to the base substrate 1. The gate electrode 26 includes a side surface, and end faces at upper and lower ends. The side surface is perpendicular to the base substrate as a whole, or a partial region of a side wall corresponding to a semiconductor layer 23 that controls the gate electrode 26, and a film layer of the region is perpendicular to the base substrate 1. In an actual production process of a product, a region where bending may exist locally is also contained in the above-mentioned situations in the present application.

For a semiconductor layer 23 surrounding and insulated from the gate electrode 26, the semiconductor layer 23 may be understood as a film layer having two opposite main surfaces (referred to as two side walls of the semiconductor layer 23) and two end faces. Surface areas of the two opposite main surfaces are larger than those of the end faces. For example, the semiconductor layer 23 extends along the side wall of the gate electrode 26, a thickness direction of the film layer of the semiconductor layer 23 is a direction parallel to the base substrate 1, a length of the film layer extending vertically on the side wall of the gate electrode 26 is a height of the film layer, and a length of the film layer surrounding the gate electrode 26 is a width of the film layer.

In some embodiments, the second semiconductor layer 23 extends on the side wall of the gate electrode 26 to form an annular semiconductor layer extending along the direction perpendicular to the base substrate 1. In some embodiments, the semiconductor layer 23 may extend only along the direction perpendicular to the base substrate 1. In some other embodiments, the semiconductor layer 23 extends along the side wall of the gate electrode 26 or the word line 40, and a shape of the semiconductor layer 23 is adapted to a shape of the side wall of the word line 40 or the gate electrode 26.

Among them, surrounding may be understood as partially or completely surrounding the gate electrode 26 or the word line 40. In some embodiments, the surrounding may be entirely surrounding, and a cross section of the surrounded semiconductor layer 23 may be in a shape of a closed ring, and the ring shape is adapted to a shape of an outer contour of a cross section of the gate electrode 26. Exemplarily, the cross section of the gate electrode 26 is of a square structure, for example. The cross section is taken along a direction parallel to the base substrate 1. In some embodiments, the surrounding may be partially surrounding, and the cross section after surrounding is not closed, but presents a ring shape. For example, the cross section of the semiconductor layer 23 is in a ring shape with an opening.

In some embodiments, different regions of the word line 40 extending along the direction perpendicular to the base substrate 1 have a same material composition, which may be understood as being formed by using a same one-time film layer preparation process, and the same material composition may be understood as that main elements tested in materials are the same, for example, they are all made of a conductive material such as a metal or Indium Tin Oxide (ITO), but an atomic number ratio of different regions is not limited.

In some embodiments, transistors of different layers may share one ring-shaped gate insulation layer 24 extending along the direction perpendicular to the base substrate, that is, gate insulation layers 24 of the plurality of transistors are connected together to form an integral structure.

In some embodiments, the first electrode 51 and the second electrode 52 of a same transistor may be in a same conductive film layer. It may be understood that the first electrode 51 and the second electrode 52 are in a same metal film layer and are patterned from a conductive film layer, and the conductive film layer is approximately parallel to an upper surface of the base substrate 1. The first electrode 51 and the second electrode 52 may be disposed in a same layer. That is, the first electrode 51 and the second electrode 52 may be simultaneously formed through a same one-time patterning process, but the embodiments of the present disclosure are not limited thereto, and the first electrode 51 and the second electrode 52 may be respectively manufactured through different patterning processes.

In some embodiments, a gate insulation layer 24 between the gate electrode 26 and the semiconductor layers 23 is exposed between semiconductor layers 23 disposed at intervals.

In some embodiments, the plurality of transistors which are stacked may further include: insulation layers 16 and conductive layers 12 which are alternately distributed from bottom to top along the direction perpendicular to the base substrate 1 (i.e., a direction from being close to the base substrate 1 to being away from the base substrate 1); and a through hole K1 penetrating through each of the insulation layers 16 and each of the conductive layers 12. The word line 40, the gate insulation layer 24 surrounding the side wall of the word line 40, the plurality of semiconductor layers 23 surrounding the gate insulation layer 24, and protective layers 82 surrounding the semiconductor layer 23 are sequentially distributed from inside to outside in the through hole K1, and the protective layers 82 are in contact with the semiconductor layers 23. The gate insulation layer 24 is exposed between two adjacent semiconductor layers 23, and an insulation layer 16 is filled between two adjacent semiconductor layers 23, and the insulation layer 16 is in contact with the exposed gate insulation layer 24. The conductive layer 12 includes a first electrode 51 and a second electrode 52 which are independent of each other, one of the first electrode 51 and the second electrode 52 is a source of the transistor and the other is a drain of the transistor, and each of the semiconductor layers 23 is in contact with a source and a drain of a conductive layer 12 of a corresponding layer.

In some embodiments, an aperture of a first region of a conductive layer 12 corresponding to the through hole K1 may be equal to an aperture of a second region of an insulation layer 16 corresponding to the through via K1. That is, sizes and shapes of cross sections of the through hole K1 at different positions along the direction parallel to the base substrate 1 may be the same, and the through hole K1 may be manufactured through one-time etching. Only a side wall of the conductive layer 12 is exposed in the through hole K1, and only a side wall of the insulation layer 16 is exposed in the through hole K1. The semiconductor layer 23 is distributed on the side wall of the conductive layer 12. In this embodiment, the semiconductor layer 23 does not extend to reach upper and lower surfaces of the conductive layer 12. The upper surface of the conductive layer 12 is a surface away from the base substrate 1 and the lower surface of the conductive layer 12 is a surface close to the base substrate 1.

In some embodiments, the plurality of protective layers 82 may extend along the direction perpendicular to the base substrate 1 and be disconnected at upper and lower surfaces of the insulation layers 16. Each insulation layer 16 may include a lower surface on a side facing the base substrate 1 and an upper surface on a side away from the base substrate 1. A protective layer 82 is disconnected at the upper and lower surfaces of the insulation layer 16, that is, the protective layer 82 is disconnected when extending to the upper surface of the insulation layer 16, and is disconnected when extending to the lower surface of the insulation layer 16, that is, the protective layer 82 is distributed only on a film layer where the conductive layer 12 is located. When manufacturing the 3D stacked semiconductor device, the protective layer 82 is disconnected on the upper and lower surfaces of the insulation layer 16, which may facilitate removal of a semiconductor layer between layers.

In some embodiments, the protective layer 82 is in contact with a semiconductor layer 23 of a corresponding transistor, and the protective layer 82 covers a region in a side wall of the semiconductor layer 23 that is not in contact with the conductive layer 12. As shown in FIG. 1A, the side wall of the semiconductor layer 23 may include four side surfaces, one side surface is in contact with the first electrode 51, one side surface is in contact with the second electrode 52, and the remaining two side surfaces are in contact with the protective layer 82 and protected by the protective layer 82.

In some embodiments, the protective layer 82 may also be distributed on and in contact with a side wall of the conductive layer 12. As shown in FIG. 1A, the protective layer 82 is in contact with a side wall of the first electrode 51 and is in contact with a side wall of the second electrode 52, and the protective layer 82 may protect the first electrode 51 and the second electrode 52 from damaging the first electrode 51 and the second electrode 52 in a manufacturing process.

In some embodiments, a material of the protective layer 82 is different from that of the insulation layer 16. In a manufacturing process of the 3D stacked semiconductor device, an insulation film layer of a same material as the insulation layer 16 is usually filled between conductive layers, and the protective layer 82 and the insulation layer 16 are made of different materials, so that it is convenient to respectively etch the protective layer 82 and the insulation film layer in the manufacturing process of the 3D stacked semiconductor device.

In some embodiments, gate insulation layers 24 of the plurality of transistors may be connected together to form an integral structure. However, the embodiments of the present disclosure are not limited thereto, and in some embodiments, gate insulation layers 24 of transistors of different layer may be disposed at intervals in the direction perpendicular to the base substrate 1. For example, a plurality of gate insulation layers 24 of a plurality of transistors may be disconnected at side walls of the insulation layers 16.

In some embodiments, the plurality of transistors which are stacked further include a fifth insulation layer 17 covering an outer side wall of each protective layer 82. As shown in FIG. 1B, a side wall of the protective layer 82 on a side away from the semiconductor layer 23 is an outer side wall, and the outer side wall of the protective layer 82 is covered by the fifth insulation layer 17.

In some embodiments, for adjacent transistors along the direction perpendicular to the base substrate 1, projections of first electrodes 51 in the direction perpendicular to the base substrate 1 are overlapped, projections of second electrodes 52 in the direction perpendicular to the base substrate 1 are overlapped, and projections of gate electrodes 26 in the direction perpendicular to the base substrate 1 are overlapped. In a solution according to the embodiment, in a process, the first electrodes and the second electrodes stacked in multiple layers may be formed first through relative stacking of conductive layers and insulation layers and then through a mask, thus implementation of the process is simple. In addition, a structure of the 3D stacked semiconductor device may be made more compact.

In some embodiments, projections of a plurality of protective layers 82 corresponding to the plurality of transistors in the direction perpendicular to the base substrate 1 are overlapped. In the solution according to the embodiment, in a process, the plurality of protective layers 82 may be formed through one-time manufacturing process, and implementation of the process is simple. In addition, the structure of the 3D stacked semiconductor device may be made more compact.

The above-mentioned 3D stacked semiconductor device may form a 1T1C storage structure with a capacitor, or form a 2T0C storage structure with another transistor, or the like.

As shown in FIGS. 1A, 1B, and 1C, an embodiment of the present disclosure provides a 3D memory, which includes the above-mentioned 3D stacked semiconductor device, and further includes a data storage element.

In some embodiments, the data storage element is, for example, a capacitor, i.e., a 1T1C storage structure is formed. However, the embodiments of the present disclosure are not limited thereto. It may form a 2T0C storage structure with another transistor, and the like. In some embodiments, the capacitor may include a first electrode plate 41 and a second electrode plate 42, and the first electrode plate 41 is connected with a first electrode 51. In some embodiments, the first electrode plate 41 and the first electrode 51 may be connected to be of an integral structure. In some embodiments, second electrode plates 42 of a same column of capacitors of different layers may be connected to be of an integral structure. As shown in FIG. 1C, second electrode plates 42 of a first column of capacitors of different layers are connected to be of an integral structure. Second electrode plates 42 of a second column of capacitors of different layers are connected to be of an integral structure, that is, same column of the capacitors of different layers share a same electrode plate as the second electrode plate 42. In some embodiments, each capacitor may further include a second insulation layer 13 disposed between the first electrode plate 41 and the second electrode plate 42. The second insulation layer 13 serves as a medium between the first electrode plate 41 and the second electrode plate 42.

In some embodiments, second insulation layers 13 of a same column of capacitors of different layers may be connected to be of an integral structure. As shown in FIG. 1C, second insulation layers 13 of a first column of capacitors of different layers are connected to be of an integral structure. Second insulation layers 13 of a second column of capacitors of different layers are connected to be of an integral structure, that is, a same column of capacitors of different layers share a same insulation layer as a medium between electrode plates.

A transistor and a data storage element constitute a storage unit. In some embodiments, as shown in FIG. 1B, storage units in a same layer form an array distributed along a first direction X and a second direction Y, respectively, and each layer of storage units further includes a bit line 30, and the bit line 30 is connected with a second electrode 52 of a same column of transistors in a same layer. FIG. 1A shows that each layer includes three rows and two columns of storage units, but the embodiments of the present disclosure are not limited thereto, and each layer may include other rows and columns of storage units, for example, may include only one storage unit. The first direction X may be parallel to the base substrate, the second direction Y may be parallel to the base substrate, and the first direction X and the second direction Y intersect. In some embodiments, the first direction X and the second direction Y may be perpendicular to each other.

In some embodiments, second electrodes 52 of transistors of two adjacent columns of storage units are connected to form a bit line 30. Second electrodes 52 of two adjacent columns of transistors in a same layer and the bit line 30 may be connected to be of an integral structure.

In some embodiments, the bit line 30 may extend along the second direction Y.

In some embodiments, the first electrode 51 may extend along the first direction X.

In an exemplary embodiment, after a stacked structure of a conductive layer and an insulation layer is formed, a through hole penetrating through the stacked structure may be etched, a sacrificial layer is deposited within the through hole as a dummy word line, a protective layer is formed to protect a region of the dummy word line corresponding to a channel region, then the sacrificial layer is removed, and a word line and a semiconductor layer are formed within the through hole, in this case a channel region of a transistor in the semiconductor layer is protected by the protective layer, and then a channel of a parasitic transistor is exposed and removed to achieve an effect of removing the parasitic transistor.

Technical solutions of the embodiment will be further explained through a manufacturing process of the 3D stacked semiconductor device of the embodiment. A “patterning process” mentioned in the embodiments includes film layer deposition, photoresist coating, mask exposure, development, etching, photoresist stripping, and other treatments, and is a mature manufacturing process in related technologies. A known process such as sputtering, evaporation, and chemical vapor deposition may be used for deposition, and a known method may be used for etching, which is not specifically limited here. In description of the embodiments, it should be understood that a “thin film” refers to a layer of thin film made of a certain material on a base substrate using a deposition or coating process. If the “thin film” does not need a patterning process or photolithography process during the whole manufacturing process, the “thin film” may also be called a “layer”. If the “thin film” needs a patterning process or photolithography process during the whole manufacturing process, it is called a “thin film” before the patterning process and a “layer” after the patterning process. The “layer” after the patterning process or photolithography process contains at least one “pattern”.

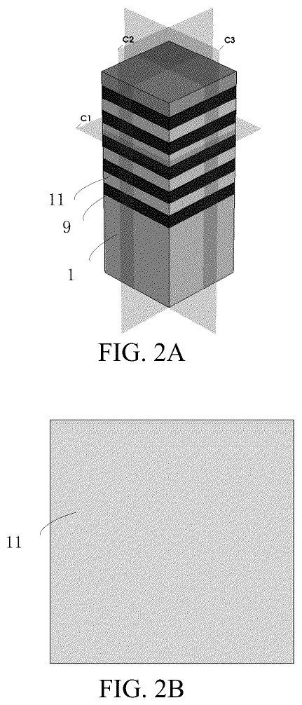

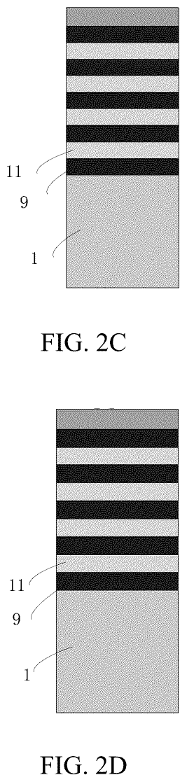

In some embodiments, the manufacturing process of the 3D stacked semiconductor device may include following steps.
1) Sequentially and alternately depositing first insulation thin films 9 and first conductive thin films 11 on a base substrate 1 to form a laminated structure, as shown in FIGS. 2A, 2B, 2C, and 2D. FIG. 2A is a three-dimensional schematic view of a 3D stacked semiconductor device, FIG. 2B is a schematic cross-sectional view of the 3D stacked semiconductor device shown in FIG. 2A along a C1 direction, FIG. 2C is a schematic cross-sectional view of the 3D stacked semiconductor device shown in FIG. 2A along a C2 direction, and FIG. 2D is a schematic cross-sectional view of the 3D stacked semiconductor device shown in FIG. 2A along a C3 direction. The C1 direction is parallel to the base substrate 1, the C2 direction is perpendicular to the base substrate 1, the C3 direction is perpendicular to the base substrate 1, and the C2 direction is perpendicular to the C3 direction.

In some embodiments, the base substrate 1 may be a semiconductor base substrate, such as a silicon base substrate.

In some embodiments, the first insulation thin film 9 may be a low-K dielectric layer, i.e., a dielectric layer with a dielectric constant K<3.9, including but not limited to a silicon oxide, such as Silicon Dioxide (SiO₂).

In some embodiments, the first conductive thin film 11 may include, but is not limited to, a multi-layer structure of Titanium Nitride (TiN)/Wolfram (W).

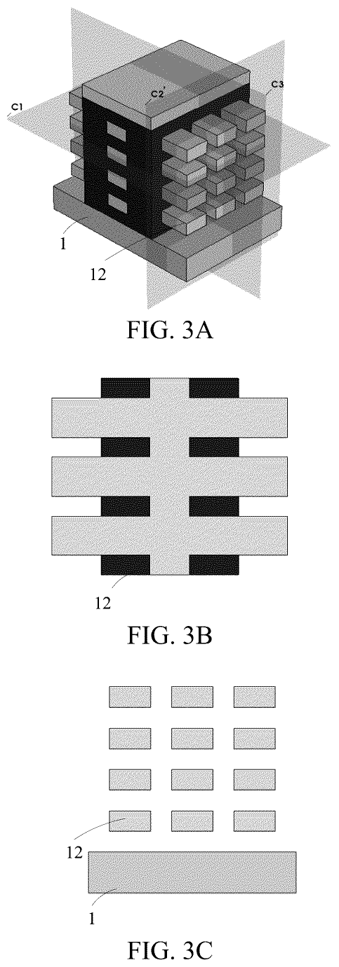

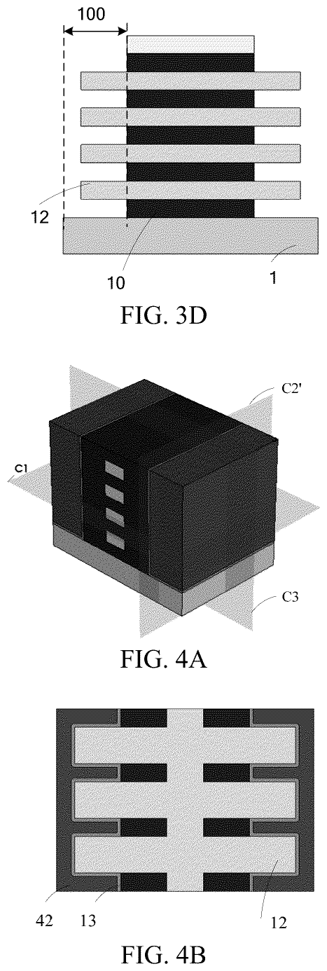

A laminated structure shown in FIG. 2A includes 5 layers of first insulation thin films 9 and 4 layers of first conductive thin films 11, for example only. In other embodiments, the laminated structure may include more or fewer layers of first insulation thin films 9 and first conductive thin films 11 alternately disposed. The laminated structure shown in FIG. 2A further includes a hard mask disposed at a top, which is used for a subsequent patterning process and is to be removed after patterning.
2) Patterning the laminated structure to form a stacked structure including conductive layers 12 and first insulation layers 10 that are alternately stacked, as shown in FIGS. 3A, 3B, 3C, and 3D. FIG. 3A is a three-dimensional schematic view of the 3D stacked semiconductor device, FIG. 3B is a schematic cross-sectional view of the 3D stacked semiconductor device shown in FIG. 3A along the C1 direction, FIG. 3C is a schematic cross-sectional view of the 3D stacked semiconductor device shown in FIG. 3A along a C2′ direction, and FIG. 3D is a schematic cross-sectional view of the 3D stacked semiconductor device shown in FIG. 3A along the C3 direction. The C2′ direction is parallel to the C2 direction.

The patterning of the laminated structure to form the stacked structure including the conductive layers 12 and the first insulation layers 10 includes: etching the laminated structure using dry etching, patterning to form the conductive layers 12, and then filling a first insulation thin film in an etched region to isolate different devices; wherein the conductive layers 12 include a preset electrode pattern, the preset electrode pattern includes a bit line to be formed and a first electrode and a second electrode of a transistor, as shown in FIG. 3B. Among them, the preset electrode pattern shown in FIG. 3B is only an example, and the preset electrode pattern may be in another shape, for example, the preset electrode pattern may be in a shape shown in FIG. 14, and the embodiments of the present disclosure are not limited thereto.

The first insulation thin films are etched (which may include anisotropic etching and isotropic etching) to remove the first insulation thin films in a capacitance region 100 to form the first insulation layer 10. At this time, an end face and part of a side wall of each conductive layer 12 located in the capacitance region 100 are exposed, and an exposed region may be used as a first electrode plate 41 of a capacitor.

A top layer of the device in FIG. 3A is a hard mask, which is to be etched away in a subsequent process.
3) Forming a second insulation layer 13 and a second electrode plate 42.

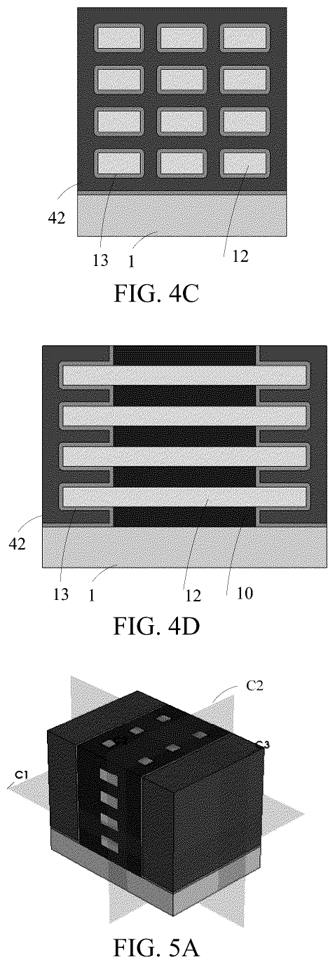

The formation of the second insulation layer 13 and the second electrode plate 42 may include: sequentially depositing a second insulation thin film and a conductor material in the capacitance region 100 to respectively form the second insulation layer 13 and the second electrode plate 42, wherein the second insulation layer 13 covers the exposed region of each conductive layer 12, as shown in FIGS. 4A, 4B, 4C, and 4D. FIG. 4A is a three-dimensional schematic view of the 3D stacked semiconductor device, FIG. 4B is a schematic cross-sectional view of the 3D stacked semiconductor device shown in FIG. 4A along the C1 direction, FIG. 4C is a schematic cross-sectional view of the 3D stacked semiconductor device shown in FIG. 4A along the C2′ direction, and FIG. 4D is a schematic cross-sectional view of the 3D stacked semiconductor device shown in FIG. 4A along the C3 direction.

Among them, the second insulation layer 13 serves as a medium between electrode plates of the capacitor, and the second electrode plate 42 serves as one electrode of the capacitor.

In some embodiments, the second insulation thin film and the conductor material may be deposited by Atomic Layer Deposition (ALD).

In some embodiments, the second insulation thin film may be made of a High-K dielectric material, i.e., a dielectric material with a dielectric constant K≥3.9. The High-K dielectric material may include, but is not limited to, at least one of: silicon oxide, Aluminum Oxide (Al₂O₃), and hafnium oxide.

In some embodiments, the conductor material includes, but is not limited to, at least one of: poly silicon, wolfram, and titanium nitride.
4) Forming a sacrificial layer 81.

The formation of the sacrificial layer 81 may include: etching the stacked structure by dry etching to form a plurality of through holes K1 penetrating through a plurality of stacked structures, wherein each conductive layer 12 is exposed by a side wall of a through hole K1; the through hole K1 may include a region corresponding to the conductive layer 12 and a region corresponding to a first insulation layer 10, that is, a region formed by the through hole K1 penetrating through the conductive layer 12 is the region of the through hole K1 corresponding to the conductive layer 12, and a region formed by the through hole K1 penetrating through the first insulation layer 10 is the region of the through hole K1 corresponding to the first insulation layer 10.

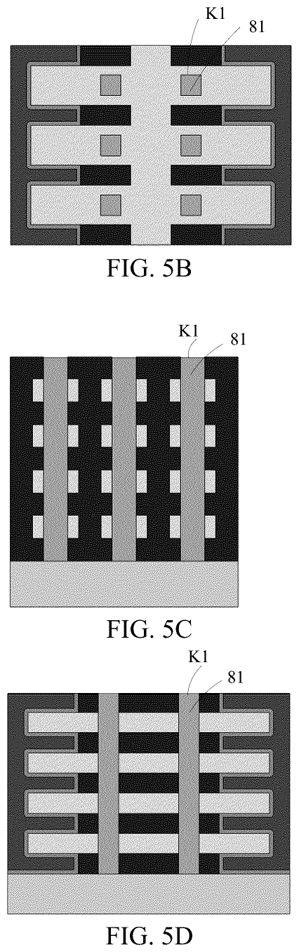

An insulation layer thin film filling each through hole K1 is deposited within each of the plurality of through holes K1 to form the sacrificial layer 81, as shown in FIGS. 5A, 5B, 5C, and 5D. FIG. 5A is a three-dimensional schematic view of the 3D stacked semiconductor device, FIG. 5B is a schematic cross-sectional view of the 3D stacked semiconductor device shown in FIG. 5A along the C1 direction, FIG. 5C is a schematic cross-sectional view of the 3D stacked semiconductor device shown in FIG. 5A along the C2 direction, and FIG. 5D is a schematic cross-sectional view of the 3D stacked semiconductor device shown in FIG. 5A along the C3 direction.

In some embodiments, an orthographic projection of each through hole K1 on a plane parallel to the base substrate 1 may be in a shape of a square or the like.

In some embodiments, the orthographic projection of each through hole K1 on the plane parallel to the base substrate 1 is within an orthographic projection of a conductive layer 12 when the through hole K1 is not formed.

In some embodiments, a material of the insulation layer thin film is different from a material of the first insulation layer 10, and the insulation layer thin film is made of, for example, Silicon Nitride (SiN).
5) Etching the first insulation thin films filled between preset electrode patterns.

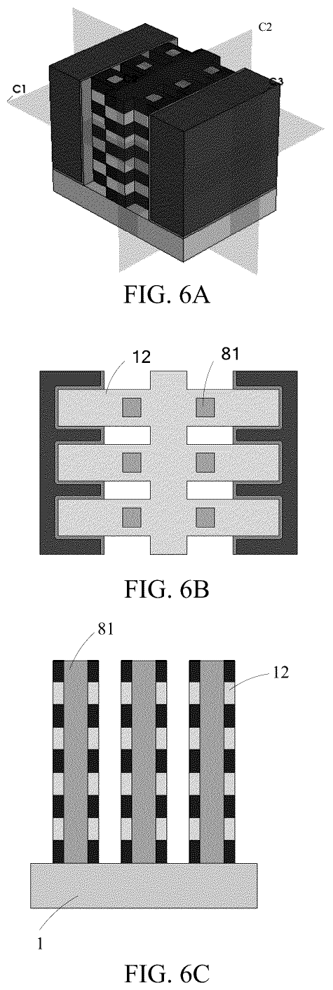

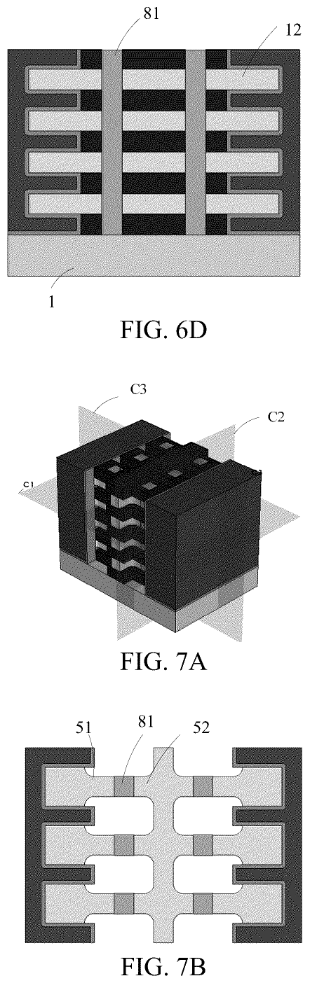

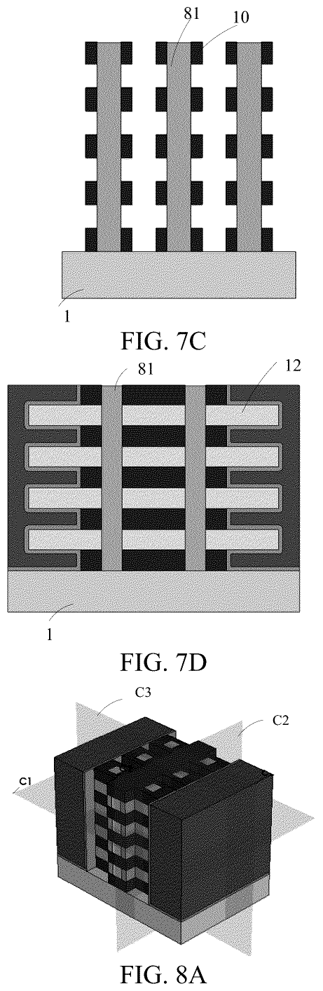

The etching of the first insulation thin films filled between the preset electrode patterns may include: etching the first insulation thin films filled between the preset electrode patterns from top to bottom of the stacked structure along the direction perpendicular to the base substrate 1 to expose side walls of the conductive layers 12 and side walls of the first insulation layers 10 located outside the capacitance region 100, as shown in FIGS. 6A, 6B, 6C, and 6D. FIG. 6A is a three-dimensional schematic view of the 3D stacked semiconductor device, FIG. 6B is a schematic cross-sectional view of the 3D stacked semiconductor device shown in FIG. 6A along the C1 direction, FIG. 6C is a schematic cross-sectional view of the 3D stacked semiconductor device shown in FIG. 6A along the C2 direction, and FIG. 6D is a schematic cross-sectional view of the 3D stacked semiconductor device shown in FIG. 6A along the C3 direction. In this case, a pattern of the first insulation layers 10 located outside the capacitance region 100 is consistent with a pattern of the conductive layers 12 located outside the capacitance region 100.
6) Etching the conductive layers 12 to expose a portion of a side wall of the sacrificial layer 81 and enable the preset electrode patterns form at least a pair of a first electrode 51 and a second electrode 52 separated from each other, wherein the first electrode 51 is in contact with the sacrificial layer 81 and the second electrode 52 is in contact with the sacrificial layer 81, as shown in FIG. 7A, FIG. 7B, FIG. 7C, and FIG. 7D. FIG. 7A is a three-dimensional schematic view of the 3D stacked semiconductor device, FIG. 7B is a schematic cross-sectional view of the 3D stacked semiconductor device of FIG. 7A along the C1 direction, FIG. 7C is a schematic cross-sectional view of the 3D stacked semiconductor device of FIG. 7A along the C2 direction, and FIG. 7D is a schematic cross-sectional view of the 3D stacked semiconductor device of FIG. 7A along the C3 direction.

One of the first electrode 51 and the second electrode 52 serves as a source electrode of a transistor and the other of the first electrode 51 and the second electrode 52 serves as a drain electrode of the transistor.

In this step, the first insulation layers 10 are not etched, that is, a pattern of the first insulation layers 10 remains unchanged and is consistent with a pattern of the conductive layers 12 when the step 6) is not performed, that is, consistent with the pattern of the conductive layers 12 shown in FIG. 6B.
7) Forming protective layers 82.

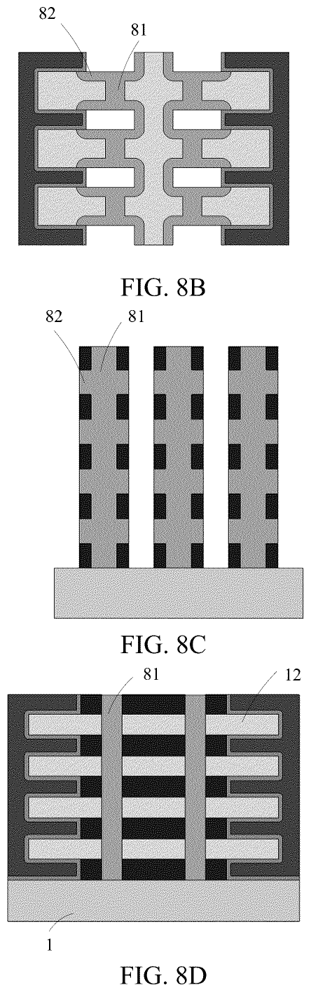

The formation of the protective layers 82 may include: depositing a protective layer thin film on a side wall of each conductive layer 12, the side wall of the sacrificial layer 81 (i.e., the side wall of the sacrificial layer 81 exposed in the step 6)), and a side wall of each first insulation layer 10, anisotropically etching the protective layer thin film, for example, etching the protective layer thin film from top to bottom along the direction perpendicular to the base substrate 1 to remove the protective layer thin film located on the side walls of the first insulation layers 10 to form the protective layers 82 covering the side walls of the conductive layer 12 and the side wall of the sacrificial layer 81, wherein the protective layers 82 fills regions where the conductive layers 12 are etched in the step 7), that is, a pattern formed by both the protective layers 82 and the conductive layers 12 is consistent with the pattern of the conductive layers 12 that is not etched, that is, consistent with the pattern of the conductive layers 12 in the step 5), as shown in FIG. 8A, FIG. 8B, FIG. 8C, and FIG. 8D. FIG. 8A is a three-dimensional schematic view of the 3D stacked semiconductor device, FIG. 8B is a schematic cross-sectional view of the 3D stacked semiconductor device shown in FIG. 8A along the C1 direction, FIG. 8C is a schematic cross-sectional view of the 3D stacked semiconductor device shown in FIG. 8A along the C2 direction, and FIG. 8D is a schematic cross-sectional view of the 3D stacked semiconductor device shown in FIG. 8A along the C3 direction.

The protective layers 82 may cover the side walls of the conductive layer 12, a plurality of protective layers 82 extend along a direction perpendicular to the base substrate 1, the plurality of protective layers 82 are disposed at intervals along the direction perpendicular to the base substrate 1, and are disconnected at the side walls of the first insulation layers 10. The protective layers 82 are in contact with the side wall of the sacrificial layer 81. Each protective layer 82 may include a first portion disposed on a first side of the sacrificial layer 81 and a second portion disposed on a second side of the sacrificial layer 81, and the first side and the second side may be opposite sides. The protective layer 82 may protect a semiconductor layer serving as a channel region of a transistor when the semiconductor layer of a parasitic transistor is to be etched subsequently.

When the protective layers 82 are formed, a protective layer thin film may be deposited on side walls of the conductive layer 12 and the sacrificial layer 81 and then etched to form the protective layers 82; or, a protective layer thin film may be deposited on the base substrate 1 to fill a blank region formed by etching in the laminated structure, and then the protective layer thin film may be etched to form the protective layers 82.

In some embodiments, a material of the protective layer thin film is different from a material of the first insulation layers 10, facilitating independent etching of the protective layers 82 and the first insulation layers 10.

In some embodiments, a material of the protective layer thin film may be the same as that of the sacrificial layer thin film, but it is not limited thereto.

In some embodiments, the protective layer thin film may include, but is not limited to, SiN.
8) Removing the sacrificial layer 81.

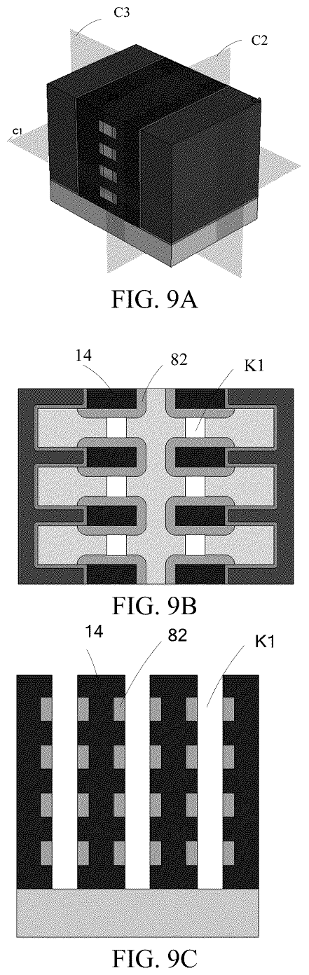

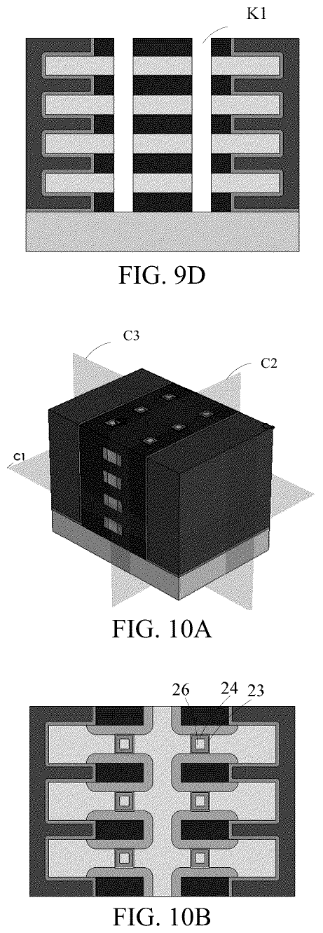

The removal of the sacrificial layer 81 may include: depositing a third insulation thin film on the base substrate on which the aforementioned patterns are formed; grinding the third insulation thin film flat to form a third insulation layer 14, and exposing a surface of the sacrificial layer 81 away from the base substrate 1; removing the sacrificial layer 81 in each through hole K1 through anisotropic etching, for example, etching from top to bottom of the through hole K1 along the direction perpendicular to the base substrate to remove the sacrificial layer 81, as shown in FIGS. 9A, 9B, 9C, and 9D. FIG. 9A is a three-dimensional schematic view of the 3D stacked semiconductor device, FIG. 9B is a schematic cross-sectional view of the 3D stacked semiconductor device shown in FIG. 9A along the C1 direction, FIG. 9C is a schematic cross-sectional view of the 3D stacked semiconductor device shown in FIG. 9A along the C2 direction, and FIG. 9D is a schematic cross-sectional view of the 3D stacked semiconductor device shown in FIG. 9A along the C3 direction.
9) Forming a semiconductor layer 23, a gate insulation layer 24, and a gate electrode 26.

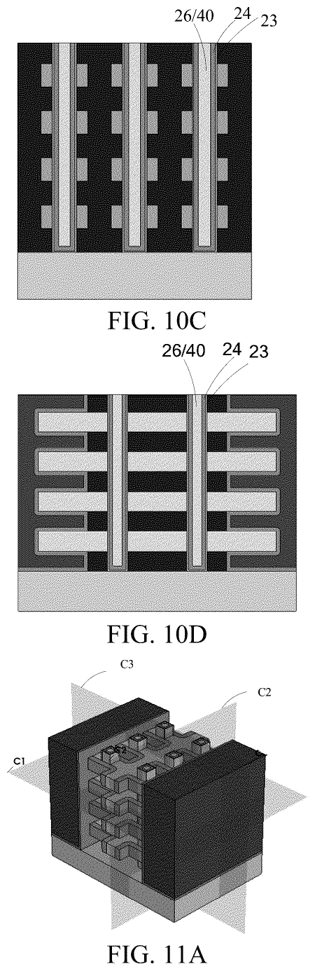

The formation of the semiconductor layer 23, the gate insulation layer 24, and the gate electrode 26 may include: sequentially depositing a semiconductor thin film and a gate insulation thin film on a side wall of each through hole K1, and depositing a gate electrode thin film filling the through hole K1, so as to sequentially forming the semiconductor layer 23, the gate insulation layer 24, and the gate electrode 26, as shown in FIG. 10A, FIG. 10B, FIG. 10C, and FIG. 10D. FIG. 10A is a three-dimensional schematic view of the 3D stacked semiconductor device, FIG. 10B is a schematic cross-sectional view of the 3D stacked semiconductor device shown in FIG. 10A along the C1 direction, FIG. 10C is a schematic cross-sectional view of the 3D stacked semiconductor device shown in FIG. 10A along the C2 direction, and FIG. 10D is a schematic cross-sectional view of the 3D stacked semiconductor device shown in FIG. 10A along the C3 direction.

In some embodiments, the semiconductor thin film includes, but is not limited to, at least one of: Indium Gallium Zinc Oxide (InGaZnO), Indium Zinc Oxide (InZnO), Indium Gallium Oxide (InGaO), Indium Tin Oxide (InSnO), Indium Gallium Tin Oxide (InGaSnO), Indium Gallium Zinc Tin Oxide (InGaZnSnO), Indium Oxide (InO), Tin Oxide (SnO), Zinc Tin Oxide (ZnSnO, ZTO), Indium Aluminum Zinc Oxide (InAlZnO), Zinc Oxide (ZnO), Indium Gallium Silicon Oxide (InGaSiO), Indium Wolfram Oxide (InWO, IWO), Titanium Oxide (TiO), Zinc Nitride (ZnON), Magnesium Zinc Oxide (MgZnO), Zirconium Indium Zinc Oxide (ZrInZnO), Hafnium Indium Zinc Oxide (HfInZnO), Tin Indium Zinc Oxide (SnInZnO), Aluminum Tin Indium Zinc Oxide (AlSnInZnO), Silicon Indium Zinc Oxide (SiInZnO), Aluminum Ainc Tin Oxide (AlZnSnO), Gallium Zinc Tin Oxide (GaZnSnO), Zirconium Zinc Tin Oxide (ZrZnSnO), and another material, as long as a leakage current of a transistor can meet requirements, it may be adjusted according to an actual situation.

In some embodiments, the gate insulation thin film may be made of a High-K dielectric material, such as a dielectric material with a dielectric constant K≥3.9. In some embodiments, an oxide of one or more of hafnium, aluminum, lanthanum, zirconium, and the like may be included. Exemplarily, for example, the High-K dielectric material may include, but is not limited to, at least one of following: Hafnium Oxide (HfO₂), Aluminium Oxide (Al₂O₃), Hafnium Aluminum Oxide (HfAlO), Hafnium Lanthanum Oxide (HfLaO), Zirconium Oxide (ZrO₂), and other High-K materials.

In some embodiments, a material of the gate electrode may be one or more of following different types of materials.

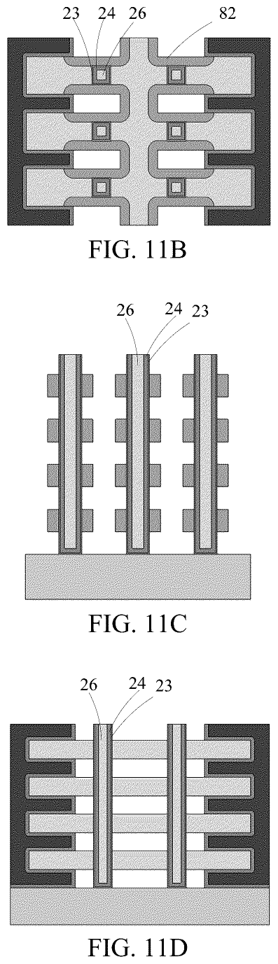

For example, the material of the gate electrode includes Wolfram, aluminum, titanium, copper, nickel, platinum, ruthenium, molybdenum, gold, iridium, rhodium, tantalum, cobalt, etc.; it may be a metal alloy containing the aforementioned metals; it may also be a metal oxide, a metal nitride, a metal silicide, a metal carbide, etc., such as tin-doped indium oxide ITO, indium-doped zinc oxide IZO, indium oxide InO, Al-doped ZnO (AZO), Iridium Oxide (IrOx), Ruthenium Oxide (RuOx), and another metal oxide conductive material; for example, Titanium Nitride (TiN), Tantalum Nitride (TaN), Wolfram Nitride (WN), Titanium Aluminum Nitride (TiAlN), and another metal nitride material.
10) Etching the first insulation layers 10 and the third insulation layer 14 to expose the semiconductor layer 23 within regions of each through hole K1 corresponding to the first insulation layers 10, and expose the side wall of the protective layer 82, as shown in FIGS. 11A, 11B, 11C, and 11D. FIG. 11A is a three-dimensional schematic view of the 3D stacked semiconductor device, FIG. 11B is a schematic cross-sectional view of the 3D stacked semiconductor device shown in FIG. 11A along the C1 direction, FIG. 11C is a schematic cross-sectional view of the 3D stacked semiconductor device shown in FIG. 11A along the C2 direction, and FIG. 11D is a schematic cross-sectional view of the 3D stacked semiconductor device shown in FIG. 11A along the C3 direction. Among them, the semiconductor layer 23 within a region of each through hole K1 corresponding to a conductive layer 12 is not exposed, and the side wall of the semiconductor layer 23 within the region is partly covered by the conductive layer 12 and partly covered by the protective layer 82, so that a damage in a subsequent step may be avoided.

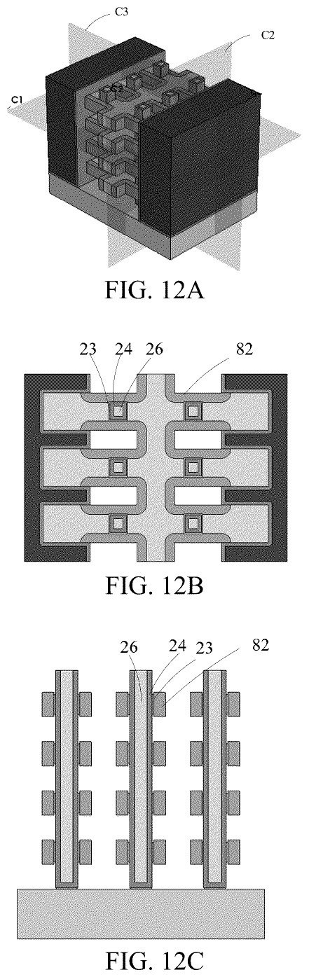

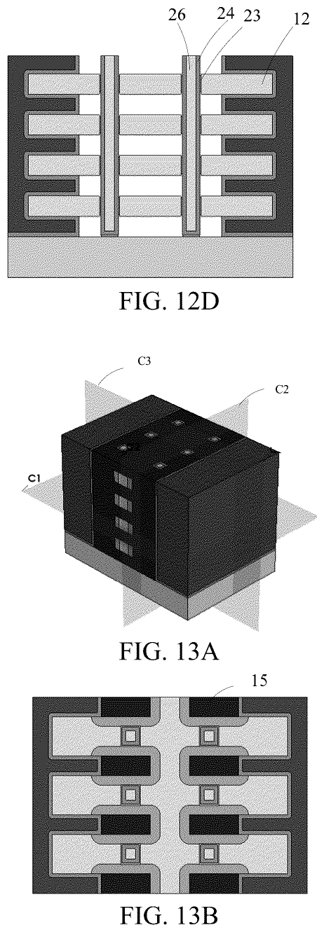

The etching of the first insulation layers 10 and the third insulation layer 14 may include: removing the third insulation layer 14 through dry etching and removing the first insulation layers 10 covering the side wall of the semiconductor layer 23 through wet etching.
11) Etching the exposed semiconductor layer 23, that is, etching the semiconductor layer 23 within regions of each through hole K1 corresponding to the first insulation layers 10, as shown in FIGS. 12A to 12D. FIG. 12A is a three-dimensional schematic view of the 3D stacked semiconductor device, FIG. 12B is a schematic cross-sectional view of the 3D stacked semiconductor device shown in FIG. 12A along the C1 direction, FIG. 12C is a schematic cross-sectional view of the 3D stacked semiconductor device shown in FIG. 12A along the C2 direction, and FIG. 12D is a schematic cross-sectional view of the 3D stacked semiconductor device shown in FIG. 12A along the C3 direction. By etching the semiconductor layer 23 within the region of each through hole K1 corresponding to the first insulation layers 10, a parasitic transistor may be removed and device performance may be improved. It may be seen that the semiconductor layer 23 is etched into a plurality of segments arranged at intervals and each segment serves as a semiconductor layer of one transistor.
12) Forming a fourth insulation layer 15.

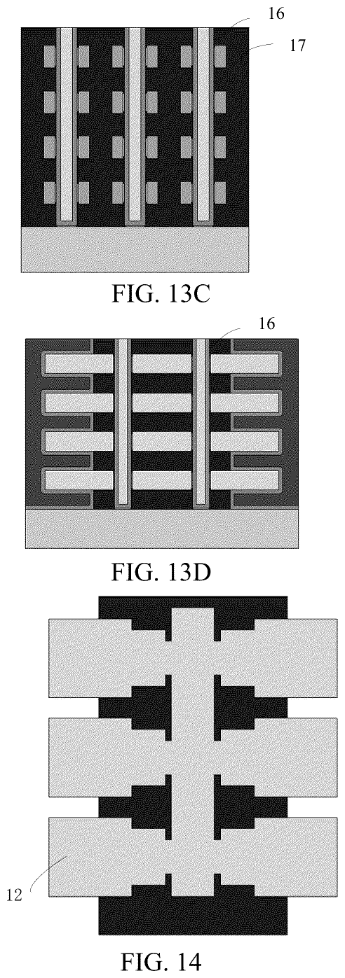

The formation of the fourth insulation layer 15 may include: filling a fourth insulation thin film on the base substrate on which the aforementioned patterns are formed and grinding it flat to form the fourth insulation layer 15, as shown in FIGS. 13A, 13B, 13C, and 13D. FIG. 13A is a three-dimensional schematic view of the 3D stacked semiconductor device, FIG. 13B is a schematic cross-sectional view of the 3D stacked semiconductor device shown in FIG. 13A along the C1 direction, FIG. 13C is a schematic cross-sectional view of the 3D stacked semiconductor device shown in FIG. 13A along the C2 direction, and FIG. 13D is a schematic cross-sectional view of the 3D stacked semiconductor device shown in FIG. 13A along the C3 direction. The fourth insulation layer 15 may include two portion, one of which is an insulation layer 16 located between adjacent conductive layers 12, and the other of which fills a region between electrodes of conductive layers 12, i.e., a fifth insulation layer 17.

In a solution according to this embodiment, after a through hole is formed, a sacrificial layer is formed as a dummy word line, a conductive layer in a channel region around the dummy word line is removed, a protective layer (or called an inner spacer) is formed in the channel region, the sacrificial layer is removed to form a semiconductor layer and a gate electrode, and then a channel of a parasitic transistor is exposed, at this time a channel of a device is protected by the protective layer, so that the channel of the parasitic transistor may be selectively removed and a purpose of removing the parasitic transistor is finally achieved. The solution according to this embodiment can effectively eliminate the parasitic transistor, and there is no need to expose the channel of the device in a later stage, thus a risk that the channel is exposed and damaged is avoided, and reliability and stability of a material of the channel of the device are ensured. In addition, the manufacturing method of this embodiment may be achieved by utilizing existing mature manufacturing equipment, and can be well compatible with an existing manufacturing process, so that a process is simple to achieve, easy to implement, high in production efficiency, and has advantages of easy process achievement, a low production cost, a high yield, and the like.

An embodiment of the present disclosure further provides an electronic equipment including the 3D stacked semiconductor device described in any of the aforementioned embodiments. The electronic device may be a storage device, a smart phone, a computer, a tablet computer, an artificial intelligence device, a wearable device or a mobile power supply, etc. The storage device may include a memory in a computer or the like, and this is not restricted here.

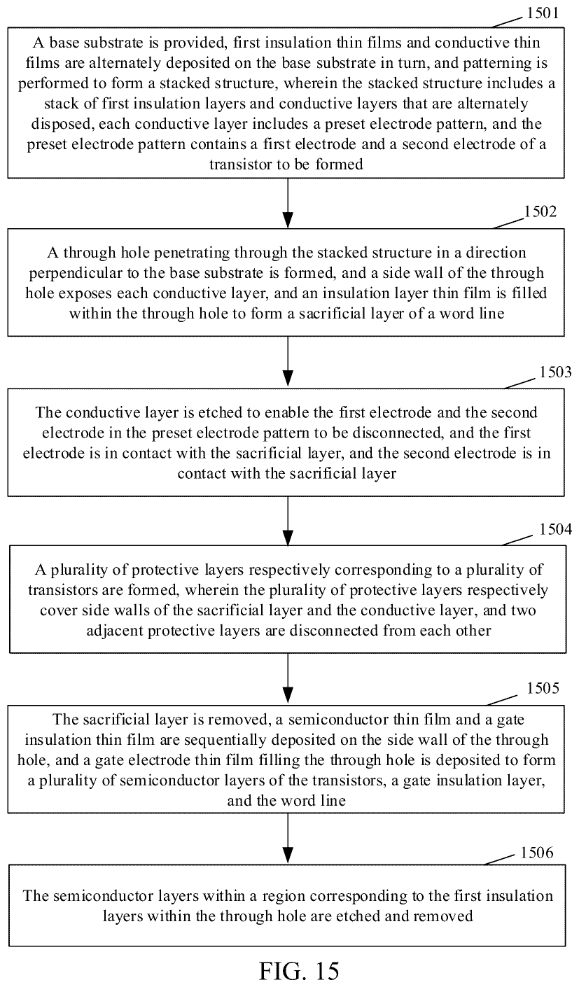

FIG. 15 is a flowchart of a method for manufacturing a 3D stacked semiconductor device according to an embodiment of the present disclosure. As shown in FIG. 15, the embodiment provides a method for manufacturing a 3D stacked semiconductor device, and the 3D stacked semiconductor device may include: a plurality of transistors distributed in different layers and stacked along a direction perpendicular to a base substrate; a word line penetrating through the transistors of the different layers; and a plurality of protective layers respectively corresponding to the plurality of transistors. The method for manufacturing the 3D stacked semiconductor device includes following steps.

In step 1501, a base substrate is provided, first insulation thin films and conductive thin films are alternately deposited on the base substrate in turn, and patterning is performed to form a stacked structure, wherein the stacked structure includes a stack of first insulation layers and conductive layers that are alternately disposed, each conductive layer includes a preset electrode pattern, and the preset electrode pattern contains a first electrode and a second electrode of a transistor to be formed.

In step 1502, a through hole penetrating through the stacked structure in the direction perpendicular to the base substrate is formed, and a side wall of the through hole exposes each conductive layer, and an insulation layer thin film is filled within the through hole to form a sacrificial layer of a word line.

In step 1503, the conductive layer is etched to expose part of a side wall of the sacrificial layer, so that the first electrode and the second electrode in the preset electrode pattern are disconnected from each other, and the first electrode is in contact with the sacrificial layer, and the second electrode is in contact with the sacrificial layer.

In step 1504, a plurality of protective layers respectively corresponding to the plurality of transistors are formed, wherein the plurality of protective layers respectively cover the side wall of the sacrificial layer and the conductive layer, and two adjacent protective layers are disconnected from each other.

In step 1505, the sacrificial layer is removed, a semiconductor thin film and a gate insulation thin film are sequentially deposited on the side wall of the through hole, and a gate electrode thin film filling the through hole is deposited to form a plurality of semiconductor layers a gate insulation layers of the transistors, and the word line, wherein the semiconductor layers are in contact with the first electrode, the second electrode, and the protective layer; gate electrodes of the transistors of different layers are part of the word line.

In step 1506, the semiconductor layers within regions corresponding to the first insulation layers within the through hole are etched and removed.

In the method for manufacturing the semiconductor device according to this embodiment, a sacrificial layer is formed within a through hole and a protective layer covering a region of the sacrificial layer corresponding to a channel region is formed, which achieves protection of the channel region, facilitates subsequent etching of a semiconductor layer between layers, achieves a purpose of removing a parasitic transistor, and improves device performance and device stability.

In some embodiments, before etching the conductive layer, the method further includes: etching from top to bottom of the stacked structure along the direction perpendicular to the base substrate to expose side walls of the conductive layers and side walls of the first insulation layers.

Forming the plurality of protective layers corresponding to the plurality of transistors respectively includes: depositing a protective layer thin film on side walls of the conductive layers, the side wall of the sacrificial layer, and side walls of the first insulation layers, etching the protective layer thin film from top to bottom of the stacked structure along the direction perpendicular to the base substrate to remove the protective layer thin film located on the side walls of the first insulation layers, so as to form the protective layers covering the side walls of the conductive layers and the side wall of the sacrificial layer.

In some embodiments, after forming the protective layers and before removing the sacrificial layer, the method further includes: depositing a third insulation thin film, and forming a third insulation layer disposed on side walls of the protective layer and the side walls of the first insulation layer.

Before etching and removing the semiconductor layers within the regions corresponding to the first insulation layers within the through hole, the method further includes: etching the third insulation layer and the first insulation layers to expose side walls of the protective layer and side walls of the semiconductor layer within the regions corresponding to the first insulation layers within the through hole.

Although implementations disclosed in the present disclosure are as described above, the described contents are only implementations used for facilitating understanding of the present disclosure, but are not intended to limit the present disclosure. Without departing from the spirit and scope disclosed in the present disclosure, any person skilled in the art to which the present disclosure pertains may make any modifications and changes in the form and details of implementation, but the scope of patent protection of the present disclosure shall still be defined by the appended claims.

1. A three-dimensional (3D) stacked semiconductor device, comprising:
a plurality of transistors distributed in different layers and stacked along a direction perpendicular to a base substrate;
a word line penetrating through the transistors of the different layers; and
a plurality of protective layers respectively corresponding to the plurality of transistors;
wherein each transistor comprises a semiconductor layer surrounding a side wall of the word line, and a gate insulation layer disposed between the side wall of the word line and the semiconductor layer;
a plurality of semiconductor layers of the plurality of transistors are disposed at intervals in a direction in which the word line extends; and
each of the protective layers respectively surrounds and covers an outer side wall of a corresponding semiconductor layer, and two adjacent protective layers are disconnected from each other.

2. The 3D stacked semiconductor device according to claim 1, wherein the plurality of stacked transistors comprise:
insulation layers and conductive layers alternately distributed in turn from bottom to top along the direction perpendicular to the base substrate; and
a through hole penetrating through each of the insulation layers and each of the conductive layers, wherein the word line, the gate insulation layers surrounding the side wall of the word line, the plurality of semiconductor layers surrounding the gate insulation layers, the protective layers surrounding the semiconductor layers are sequentially distributed within the through hole from inside to outside, and the protective layers are in contact with the semiconductor layers;
wherein each gate insulation layer is exposed between two adjacent semiconductor layers, each insulation layer is filled between two adjacent semiconductor layers, and the insulation layer is in contact with the exposed gate insulation layer; and
each conductive layer comprises a first electrode and a second electrode which are independent of each other, one of the first electrode and the second electrode is a source of a transistor, and the other of the first electrode and the second electrode is a drain of the transistor.

3. The 3D stacked semiconductor device according to claim 2, wherein an aperture of the through hole corresponding to a first region of the conductive layer is equal to an aperture of the through hole corresponding to a second region of the insulation layer;
only a side wall of the conductive layer is exposed within the through hole, and only a side wall of the insulation layer is exposed within the through hole; and
a semiconductor layer is distributed on the side wall of the conductive layer.

4. The 3D stacked semiconductor device according to claim 2, wherein the plurality of protective layers extend along the direction perpendicular to the base substrate and are disconnected at upper and lower surfaces of the insulation layers.

5. The 3D stacked semiconductor device according to claim 2, wherein each protective layer is in contact with a semiconductor layer of a corresponding transistor, and the protective layer covers a region in a side wall of the semiconductor layer that is not in contact with the conductive layer.

6. The 3D stacked semiconductor device according to claim 2, wherein the protective layers are further distributed on side walls of the conductive layers and in contact with the side wall of the conductive layer.

7. The 3D stacked semiconductor device according to claim 2, wherein a material of the protective layers is different from a material of the insulation layers.

8. The 3D stacked semiconductor device according to claim 2, wherein the plurality of stacked transistors further comprise a fifth insulation layer covering outer side walls of the protective layers.

9. An electronic equipment, comprising the 3D stacked semiconductor device according to claim 1.

10. A method for manufacturing a 3D stacked semiconductor device, wherein the 3D stacked semiconductor device comprises: a plurality of transistors distributed in different layers and stacked along a direction perpendicular to a base substrate; a word line penetrating through the transistors of the different layers; and a plurality of protective layers respectively corresponding to the plurality of transistors; the method for manufacturing the 3D stacked semiconductor device comprises:
providing a base substrate, alternately depositing first insulation thin films and conductive thin films in turn on the base substrate, and patterning to form a stacked structure, wherein the stacked structure comprises a stack of first insulation layers and conductive layers that are alternately disposed, each conductive layer comprises a preset electrode pattern, and the preset electrode pattern contains a first electrode and a second electrode of a transistor to be formed;
forming a through hole penetrating through the stacked structure in the direction perpendicular to the base substrate, wherein a side wall of the through hole exposes each conductive layer, and filling an insulation thin film within the through hole to form a sacrificial layer of the word line;
etching each conductive layer to expose a portion of a side wall of the sacrificial layer to enable the first electrode and the second electrode in the preset electrode pattern to be disconnected from each other, wherein the first electrode is in contact with the sacrificial layer and the second electrode is in contact with the sacrificial layer;
forming a plurality of protective layers respectively corresponding to the plurality of transistors, wherein the plurality of protective layers respectively cover side walls of the sacrificial layer and the conductive layers, and two adjacent protective layers are disconnected from each other;
removing the sacrificial layer, sequentially depositing a semiconductor thin film and a gate insulation thin film on the side wall of the through hole, and depositing a gate electrode thin film filling the through hole to form a plurality of semiconductor layers and gate insulation layers of the transistors, and the word line, wherein the semiconductor layers are in contact with the first electrodes, the second electrodes, and the protective layers; gate electrodes of the transistors of different layers are part of the word line; and
etching and removing the semiconductor layers within regions corresponding to the first insulation layers within the through hole.

11. The method for manufacturing the 3D stacked semiconductor device according to claim 10, wherein
before etching the conductive layers, the method further comprises: etching from top to bottom of the stacked structure along the direction perpendicular to the base substrate to expose side walls of the conductive layers and side walls of the first insulation layers;
forming the plurality of protective layers corresponding to the plurality of transistors respectively comprises:
depositing a protective layer thin film on the side walls of the conductive layers, the side wall of the sacrificial layer, and the side walls of the first insulation layers, etching the protective layer thin film from top to bottom along the direction perpendicular to the base substrate to remove the protective layer thin film located on the side walls of the first insulation layers, and forming the protective layers covering the side walls of the conductive layers and the side wall of the sacrificial layer.

12. The method for manufacturing the 3D stacked semiconductor device according to claim 10, wherein
after forming the protective layers and before removing the sacrificial layer, the method further comprises: depositing a third insulation thin film, and forming a third insulation layer disposed on side walls of the protective layers and side walls of the first insulation layers;
before etching and removing the semiconductor layers within the regions corresponding to the first insulation layers within the through hole, the method further comprises:
etching the third insulation layer and the first insulation layers to expose the side walls of the protective layers and the side walls of the semiconductor layers within the regions corresponding to the first insulation layers within the through hole.
